(19) United States
(12) Patent Application Publication
(10) Pub. No.: US 2013/0255740 A1
(43) Pub. Date: Oct. 3, 2013

(54) THERMOGENERATOR AND PROCESS FOR PRODUCING A THERMOGENERATOR

(71) Applicants: Gaelle Delaizir, Plescop (FR); Judith Monnier, Rosny-sous-bois (FR); Claude Godart, La Baule (FR); Christelle Navone, St.-jean de Moirans (FR); Johann Testard, Veyrier (FR)

(72) Inventors: Gaelle Delaizir, Plescop (FR); Judith Monnier, Rosny-sous-bois (FR); Claude Godart, La Baule (FR); Christelle Navone, St.-jean de Moirans (FR); Johann Testard, Veyrier (FR)

(73) Assignee: COMMISSARIAT A L'ENERGIE ATOMIQUE ET AUX ENERGIES ALTTERNATIVES, Paris (FR)

(21) Appl. No.: 13/992,353

(22) PCT Filed: Dec. 6, 2011
(86) PCT No.: PCT/FR11/52885

§ 371 Date: Jun. 7, 2013

(30) Foreign Application Priority Data
Dec. 10, 2010 (FR) 1060389

(51) Int. Cl. H01L 35/32; H01L 35/34

(52) U.S. Cl. CPC H01L 35/32; H01L 35/34
USPC 136/205; 438/54; 136/201

(57) ABSTRACT

The invention relates to a process for producing a thermogenerator (10) comprising a plurality of thermocouples formed of p-type thermoelements (12) and n-type thermoelements (14). A wafer (18), provided with a plurality of holes (20a, 20b) is covered in thermoelectric material powder (22, 24). Pressure (P) is applied to the powder (22, 24) so that it penetrates into the holes (20a, 20b) while heating so as to form a plurality of p-type and n-type thermoelements (12, 14) contained in the wafer (18). The wafer (18) is thinned, the thinned wafer thus forming a matrix (16) in which the thermoelements (12, 14) are contained. While preserving the matrix (16) the p-type thermoelements are connected so as to form thermocouples and the n-type thermoelements are connected so as to form thermocouples, thereby obtaining a thermogenerator (10).

This invention relates to thermogenerators comprising a plurality of thermocouples formed of p-type thermoelements and n-type thermoelements. These thermocouples are associated as they are in a thermoelectric module. A module consists of electrically connected couples. Each of the thermocouples is composed of p-type material (Seebeck coefficient S>0) and n-type material (Seebeck coefficient S<0), respectively having hole conduction and electron conduction. The component materials of the thermoelements are joined by a conducting material whose thermopower is assumed to be zero. The two branches (p and n) of the thermocouple and all thermocouples forming the module are electrically connected in series, and thermally connected in parallel. These modules can be used, depending on the component materials, in cooling (Peltier effect) or in generating electricity (thermogenerator, Seebeck effect).

The invention concerns a method for producing thermogenerators.

It more particularly relates to a thermogenerator comprising a plurality of thermocouples formed by alternating p-type and n-type thermoelements, located in the same plane. The step of placing the thermoelements into the insulating matrix, including their densification, is performed in a single step by means of sintering.

Known thermogenerators allow recovering energy when there is a heat source creating a temperature gradient. In the case of materials based on Bi₂Te₃, the heat source is at a moderate temperature, generally below 200° C. This heat source can be in gas, solid, and/or possibly liquid form.

At present, thermoelectricity is particularly useful in cooling applications, often with a low power draw (mini-bars, etc.). Electrical power generation applications, although less developed, involve much higher power levels, because in any industrial environment, a significant, and even major, fraction of the energy consumed by the systems is often pointlessly released as heat. Due to the low efficiency of thermoelectric materials and the complex design of thermogenerators, the energy recovery solutions are inefficient, expensive, and difficult to implement. In the field of small temperature gradients with ambient temperature, two cases can occur:
either the thermal energy is dissipated by thermoelectric cooling, a system that is more reliable than fans for protecting a device, which is the case for example for electronic components;
or the waste heat is used to recover appreciable energy, because it is linked to the operation of the system, even if efficiency is low (a few percentage points).

Known thermoelectric modules, particularly those based on Bi₂Te₃, generally have a small surface area of at most a few square centimeters.

Generally, the conventional geometry of known thermogenerators comprising thermoelements and their connections are inserted between supports which are generally aluminum oxide, silicon, or other. These supports ensure the mechanical rigidity of the unit. The thermoelements electrically interconnected between these supports are surrounded by air or, in some cases, by thermally insulating materials, thus avoiding possible corrosion.

Thus the known thermogenerators do not allow producing electricity at reasonable costs, due to their low efficiency and high production costs (the labor required to slice the p-type and n-type materials in order to produce the p-type and n-type thermoelements, and then to assemble and connect them).

The objective of this invention is to implement the production and assembly of the p-type and n-type thermoelements in a single step, and to reduce the costs drastically.

The creation of low-cost, large-surface area thermogenerators for applications that recover energy from extensive heat sources with a low temperature gradient could lead to much higher electricity production, as it would be economically competitive.

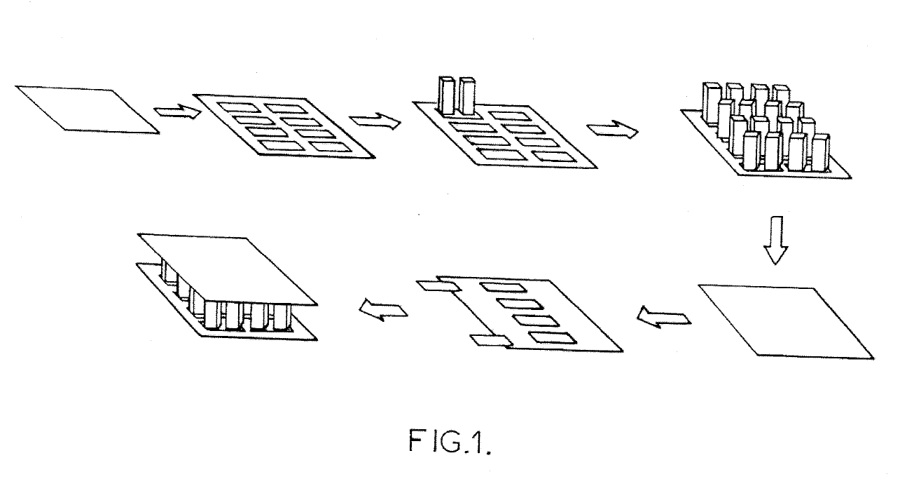

The method for producing the known thermogenerators is done, as illustrated in FIG. 1, by defining metal connections on a support and then alternately placing p-type and n-type thermoelements. This “thermoelements/metal connections and primary support” unit is then covered by another one, also equipped with metal connections. The assembly with the second support, as illustrated in FIG. 1, produces a known type of thermogenerator.

The objective of this invention is to produce thermogenerators with alternating placement of thermoelements in a plane and electrical insulation between p-type and n-type elements, in a single step; the surface areas can be larger than known thermogenerators, thereby resulting in the production of electricity at a reasonable cost based on recovering energy from low-temperature sources (in particular, lower than 200° C.).

A first object of the invention relates to a method for producing a thermogenerator comprising a plurality of thermocouples formed of p-type thermoelements and n-type thermoelements, the p-type thermoelements and n-type thermoelements respectively comprising p-type thermoelectric material and n-type thermoelectric material, characterized by performing the following steps:
a) a thermally and electrically insulating wafer is provided, the wafer having a first face and a second face, the second face being opposite the first face, the first face being provided with a plurality of first blind holes extending in the direction of the second face, the second face being provided with a plurality of second blind holes extending in the direction of the first face, the blind holes of the two faces being staggered,
b) powder of p-type thermoelectric material and powder of n-type thermoelectric material are provided,
c) a first layer is formed from one of the powders of p-type or n-type thermoelectric material; this first layer is placed against the first face of the wafer,
d) a second layer is formed from the other of the powders of p-type or n-type thermoelectric material; this second layer is placed against the second face of the wafer,
e) a pressure is applied on the first and second layers so that the powder from the first layer penetrates into the first holes and the powder from the second layer penetrates into the second holes,
f) heat is applied for a duration (D) at a temperature (T), so that each of the powders of p-type and n-type thermoelectric material sinters, thus forming in the first and the second holes a plurality of p-type and n-type thermoelements contained in the wafer,
g) the thickness of the wafer on the side of its second face is reduced until the thermoelements
h) the thickness of the wafer on the side of its first face is reduced until the thermoelements formed in the second holes reach the first face, the wafer, thus thinned, forms a matrix in which the thermoelements are contained, and
i) while preserving the matrix, the p-type and n-type thermoelements are connected to form thermocouples, whereby a thermogenerator is obtained.

The p-type and n-type thermoelements constituting the thermogenerator obtained by this method are thus integrated into the thermally and electrically insulating wafer (or matrix) having a final thickness equal to the final height of the thermoelements.

The thermally and electrically insulating wafer may be of any type, for example ceramic, but it can be particularly advantageous to select a low-cost polymer or plastic material which provides the wafer with some flexibility. However, this material preferably must have a melting point or a glass transition temperature that is higher than the sintering temperature (T) of the materials used to form the p-type and n-type thermoelements.

The use of a polymer or plastic material for the thermally and electrically insulating wafer allows producing low-cost components with a large surface area, the perforation of the wafer to form the blind holes being particularly easy even for very small hole diameters.

In various embodiments of the thermogenerator of the invention, it may also be possible to use one or more of the following arrangements:
Steps e) and f) are performed at the same time,
Steps e) and f) are performed by sintering, preferably by flash sintering or by using either of two hot sintering techniques: HIP (hot isostatic pressing) or HUP (hot uniaxial pressing),
The duration (D), which is variable depending on the dimensions of the wafer and of the holes as well as on the material, is less than or equal to 60 minutes, but it can also be as low as 5 minutes, particularly in the case of flash sintering. The duration (D) can in fact vary depending on the desired final particle size of the p-type and n-type thermoelements.

The invention also relates to a thermogenerator comprising a plurality of thermocouples formed from p-type thermoelements and n-type thermoelements, comprising a thermally and electrically insulating matrix in which the p-type thermoelements and the n-type thermoelements are contained.

In various embodiments of the thermogenerator of the invention, it may also be possible to use one or more of the following arrangements:
The matrix comprises a material selected from among the polymers and ceramics,
The matrix comprises a material selected from among the polymers which has a glass transition temperature higher than the sintering temperature of the p-type and n-type thermoelectric materials,
The matrix comprises a material selected from among the ceramics which has a sintering temperature higher than the sintering temperature of the p-type and n-type thermoelectric materials.

The invention will be better understood and its advantages will become more apparent upon reading the following detailed description which is only one non-limiting example of a method of the invention.

The description refers to the accompanying drawings, in which:

FIG. 1 schematically represents the method for producing a known thermogenerator,

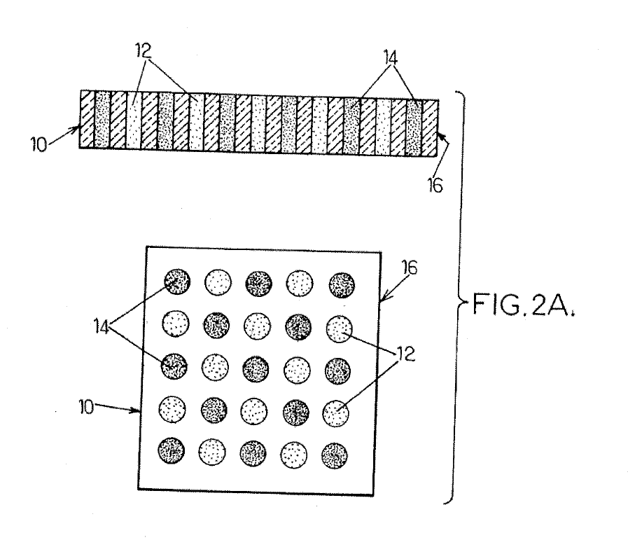

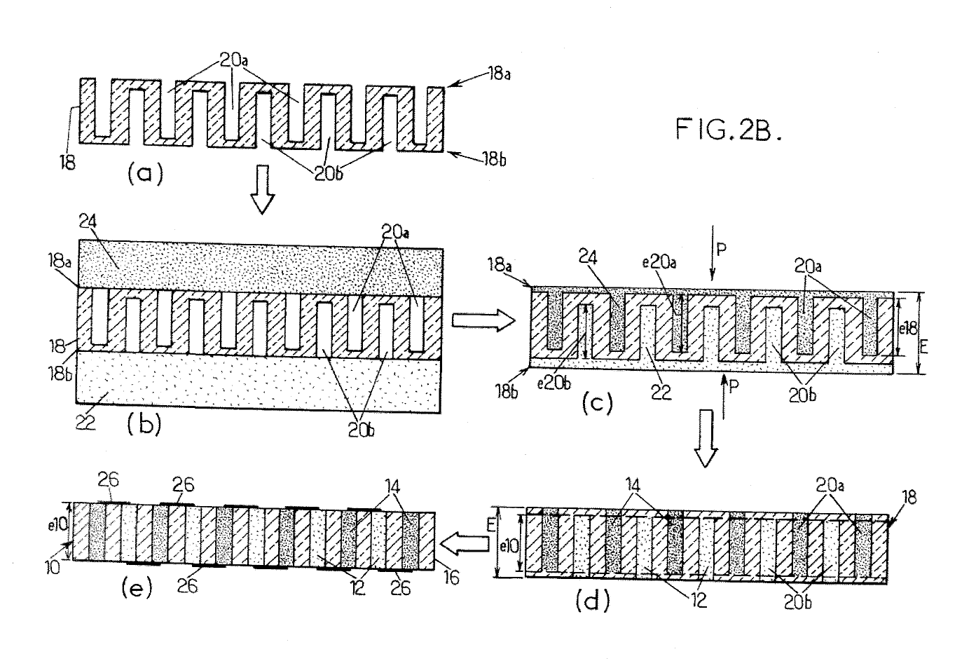

FIG. 2A represents a thermogenerator according to the invention,

FIG. 2B represents a method for producing a thermogenerator according to the invention,

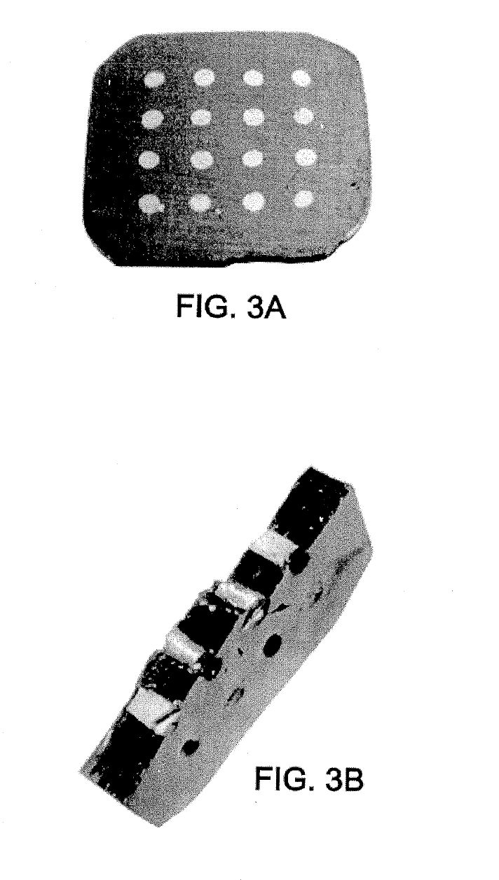

FIGS. 3A and 3B represent photographs of an example of the invention.

In FIGS. 2A and 2B, the same references indicate identical or similar components.

FIG. 2A (drawings (a) and (b)) represents a thermogenerator 10 comprising a plurality of thermocouples formed from p-type thermoelements 12 and a plurality of n-type thermoelements 14. These thermoelements 12, 14, respectively p-type and n-type, are contained in a matrix 16, as is best displayed in drawing (a) of FIG. 2A. These p-type and n-type thermoelements 12, 14 preferably alternate in the matrix (16), as illustrated for example in drawing (b) of FIG. 2A.

The matrix 16 is made from thermally insulating and electrically insulating material. The matrix 16 is therefore preferably made from a material selected from among the polymers and ceramics.

When the matrix is made from a polymer material, it must have a glass transition temperature (Tg) that is higher than the sintering temperature of the p-type and n-type thermoelectric materials. The polymer used for making the matrix 16 can be, for example, from the polyimide family, which have glass transition temperatures (Tg) exceeding 350° C. The electrically insulating matrix can also be made from a ceramic material having a sintering temperature higher than the sintering temperature of the p-type and n-type thermoelectric materials. Thus the matrix can comprise aluminum oxide, apatite, and/or glass.

To produce a thermogenerator in accordance with the invention, one proceeds as follows with reference to FIG. 2B.

As illustrated in step (a) of FIG. 2B, a thermally and electrically insulating wafer 18 is used, preferably of one of the materials mentioned above (polymer or ceramic). This wafer 18 has a first face 18a, and a second face 18b opposite the first face 18a.

The first face 18a is provided with a plurality of first holes 20a which are blind and which extend in the direction of the second face. These first holes 20 all preferably extend substantially transverse to the first face 18a of the wafer 18. The same appears for the second face 18b, which is provided with a plurality of second holes 20b also extending substantially transverse to the second face 18b. In this case, as shown in FIG. 2B, faces 18a and 18b of the parallelepiped wafer 18 are substantially flat and parallel relative to each other; it follows that the first holes 20a and the second holes 20b are substantially parallel relative to each other and extend substantially perpendicular to the two faces 18a and 18b. The wafer 18 has this plurality of first holes 20a and second holes 20b, preferably distributed evenly and with the first holes 20a and second holes 20b alternating, i.e. preferably having a second hole 20b between two first holes 20a.

As illustrated in step (b) of FIG. 2B, an amount of p-type thermoelectric powder 22 is provided as well as an amount of n-type thermoelectric powder 24. The wafer 18 is placed on the first layer of one of these powders, for example p-type powder 22, and then n-type powder 24 is placed on top of the wafer 18. In this case, the second face 18b of the wafer 18 is placed on a layer of p-type powder 22, then a layer of n-type powder 24 is placed over the first face 18a of the wafer 18. Of course, the arrangement of the faces could be reversed so that the first face 18a is placed on the layer of p-type powder 22 and the second face 18b is covered with a layer of n-type power 24. Similarly, the positions could be reversed so that first a layer of n-type powder 24 is placed, then the wafer 18, which is then covered with a layer of p-type powder 22.

As illustrated in step (c) of FIG. 2B, pressure is then applied over these p-type and n-type layers so that the powder penetrates into the respective holes. In the current example, pressure P is applied on each of the layers so that p-type powder 22 penetrates into the second holes 20b and n-type powder 24 penetrates into the first holes 20a. Preferably, pressure P of the same value is applied on both sides of the wafer 18; this uniaxial pressure allows the powder to penetrate correctly into the blind holes by filling them in a symmetric manner between the first face 18a and the second face 18b.

The wafer 18 has a thickness e18, the first blind holes 20a have a depth e20a, and the second holes 20b have a depth e20b. The depth e20a of the first holes 20a and the depth e20b of the second holes 20b are, preferably, of the same value and of course are less than the thickness e18 of the wafer 18.

This unit formed by the matrix 18 and the p-type and n-type powders 22 and 24 is heated for a duration D and at temperature T. The temperature T is greater than or equal to the sintering temperature of the p-type and n-type powders 22 and 24, so that during this heating operation the p-type powder 22 and the n-type powder 24 will sinter. In the current case, this heating operation is performed simultaneously with the application of pressure P, so that p-type powder 22 and n-type powder 24 respectively penetrate into the first and second holes, filling them completely and sintering inside them.

In order to sinter the powders in very short periods of time, the heating is performed by means of flash sintering, which is also called “spark plasma sintering” (permitting very short heating times D and reaching elevated temperatures). The total duration D of the heating (i.e. the time to reach temperature T and the period held at temperature T, excluding the cooling off period) is preferably less than or equal to 60 minutes, but can be as low as 5 minutes. Other more traditional hot sintering techniques (HIP or HUP) are also possible.

After sintering the powder, n-type thermoelements 14 and p-type thermoelements 12 are obtained in the first holes 20a. These thermoelements 12 and 14 are contained in the wafer 18 and are solidly anchored there, both mechanically and chemically. It is understood that the thermoelements 12 and 14 are, to some extent, crimped in the wafer 18.

After heating, the next step is to eliminate the excess p-type 22 and n-type 24 powder which did not penetrate into the holes 20a and 20b, as illustrated in step (d) of FIG. 2B. This reduction in the thickness of the unit is performed until the first holes 20a and the second holes 20b become through-holes.

The thickness E of the unit is reduced after sintering, for example by polishing or slicing the first and second faces, or by using another technique for removing material, in order to reduce the thickness of the unit to thickness e10. This thickness e10 corresponds to the thickness at which the first holes 20a and the second holes 20b respectively reach the second face 20b and the first face 20a. It is understood that this thickness e10 obtained after reducing the thickness E is less than or equal to the respective depth e20a and e20b of the first holes 20a and the second holes 20b.

The thickness can be reduced symmetrically or non-symmetrically. Indeed, it is understood that depending on the thickness of the remaining excess of p-type powder 22 on the first face 18a, the thickness of the remaining excess of n-type powder 24 on the second face 18b, and the respective depth e20a and e20b of the first and second holes 20a and 20b, more or less material must be removed from each side of the unit until each of the first holes 20a and each of the second holes 20b all reach the opposite face, respectively the second face 18b and the first face 18a.

After the thickness is reduced, a unit having thickness e10 is obtained, as illustrated in step (e) of FIG. 2B. This unit thus comprises a matrix 16 (corresponding to the wafer 18 of reduced thickness) in which the first holes 20a contain n-type thermoelements 14 and the second holes contain p-type thermoelements 12.

In the last step of the method, which is also illustrated in step (e) of FIG. 2B, the p-type thermoelements 12 are connected electrically to the n-type thermoelements 14 in order to form the thermocouples. This unit, formed of p-type and n-type thermocouples contained (secured) in the matrix 16, forms the thermogenerator 10 according to the invention. Thus the matrix 16 (originating from the initial wafer 18) maintains the spacing between the p-type and n-type thermocouples and holds them in place.

Below is an example of how a thermogenerator is produced (see FIGS. 3A and 3B).

### EXAMPLE

Wafer 18: kapton (polyimide family) with glass transition temperature (Tg) equal to 390° C.
Thickness e18 of the wafer: between 500 μm and 1 mm
Ø of the holes 20a and 20b: between 100 μm and 1 mm
p-type powder 22: Bi_{0.5}Sb_{1.5}Te_{3.4} with sintering temperature equal to 360° C.
n-type powder 24: Bi₂Se_{0.3}Te_{2.7} with sintering temperature equal to 360° C.

Spark Plasma Sintering Parameters:
Pressure P: 50 MPa
Temperature: 320-360° C.
Dwell time: 5 minutes
Diameter of the graphite matrix used for applying the pressure P: 8 mm.

This thermogenerator has been produced with a total duration D (temperature increase and stationary phase) of 10 minutes; in the case of flash sintering, the duration D can be reduced to 5 minutes when the temperature T is less high. Conversely, this total duration D can be increased up to 60 minutes if the temperature T is higher or in the case of conventional HUP or HIP sintering.

The thermogenerator 10 as described above can therefore be of fairly significant size, reaching several hundred millimeters in diameter.

Depending on the material selected for the wafer 18, a thermogenerator with a more or less flexible mechanical structure can be obtained. This flexibility is particularly desirable in the field of thermal energy recovery in nuclear power plants or electrical transformer substations for example (flexible thermoelectric envelope to fit around pipes at temperatures compatible with the temperature of the polymer), or for cold generation in civil or military applications (flexible cooling stretchers for the injured).

1. (canceled)

2. (canceled)

3. (canceled)

4. (canceled)

5. (canceled)

6. (canceled)

7. (canceled)

8. (canceled)

9. Method for producing a thermogenerator comprising a plurality of thermocouples formed of p-type thermoelements and n-type thermoelements, the p-type and n-type thermoelements respectively comprising p-type thermoelectric material and n-type thermoelectric material, wherein the following steps are performed:
a) a thermally and electrically insulating wafer is provided, the wafer having a first face and a second face, the second face being opposite the first face, the first face being provided with a plurality of first blind holes extending in the direction of the second face, the second face being provided with a plurality of second blind holes extending in the direction of the first face,
b) powder of p-type thermoelectric material and powder of n-type thermoelectric material are provided,
c) a first layer is formed from one of the powders of p-type and n-type thermoelectric material, the first layer is placed against the first face of the wafer,
d) a second layer is formed from the other of the powders of p-type and n-type thermoelectric material, the second layer is placed against the second face of the wafer,
e) a pressure is applied on the first and second layers so that the powder from the first layer penetrates into the first holes and the powder from the second layer penetrates into the second holes,
f) heat is applied for a duration D at a temperature T, so that each of the powders of p-type and n-type thermoelectric material sinters, thus forming in the first and the second holes a plurality of p-type and n-type thermoelements contained in the wafer,
g) the thickness of the wafer on the side of its second face is reduced until the thermoelements formed in the first holes reach the second face,
h) the thickness of the wafer on the side of its first face is reduced until the thermoelements formed in the second holes reach the first face, the wafer, thus thinned, forms a matrix in which the thermoelements are contained, and
i) while preserving the matrix, the p-type and n-type thermoelements are connected to form thermocouples, whereby a thermogenerator is obtained, said matrix allowing spacing and holding the p-type and n-type thermocouples.

10. Method for producing a thermogenerator according to claim 9, wherein steps c) and f) are performed simultaneously.

11. Method for producing a thermogenerator according to claim 9, wherein steps e) and f) are performed by sintering.

12. Method for producing a thermogenerator according to claim 9, wherein the duration D is less than or equal to 60 minutes.

13. Thermogenerator comprising a plurality of thermocouples formed from p-type thermoelements and n-type thermoelements, wherein the thermogenerator comprises a thermally and electrically insulating matrix in which the p-type thermoelements and the n-type thermoelements are contained.

14. Thermogenerator according to claim 13, wherein the matrix comprises a material selected from among the polymers and ceramics.

15. Thermogenerator according to claim 13, wherein the matrix comprises a material selected from among the polymers which has a glass transition temperature higher than the sintering temperature of the p-type and n-type thermoelectric materials.

16. Thermogenerator according to claim 13, wherein the matrix comprises a material selected from among the ceramics which has a sintering temperature higher than the sintering temperature of the p-type and n-type thermoelectric materials.

17. Thermogenerator according to claim 14, wherein the matrix comprises a material selected from among the polymers which has a glass transition temperature higher than the sintering temperature of the p-type and n-type thermoelectric materials.

18. Thermogenerator according to claim 14, wherein the matrix comprises a material selected from among the ceramics which has a sintering temperature higher than the sintering temperature of the p-type and n-type thermoelectric materials.

19. Method for producing a thermogenerator according to claim 10, wherein steps e) and f) are performed by sintering.

20. Method for producing a thermogenerator according to claim 10, wherein the duration D is less than or equal to 60 minutes.

21. Method for producing a thermogenerator according to claim 11, wherein the duration D is less than or equal to 60 minutes.
